(19) United States
(12) Patent Application Publication
(10) Pub. No.: US 2026/0282328 A1
(43) Pub. Date: Sep. 17, 2026

(54) MICROELECTRONIC DEVICES INCLUDING MULTIPLE-SURFACE CONTACTS FOR DIGIT LINE STRUCTURES AND RELATED MEMORY DEVICES AND ELECTRONIC SYSTEMS

(71) Applicant: Micron Technology, Inc., Boise, ID (US)

(72) Inventors: Tommaso Rossi, Cerro Al Lambro (IT); Marcello Mariani, Milano (IT); Yoshinori Ikebuchi, Hiroshima (JP); Eiji Hasunuma, Hiroshima (JP)

(21) Appl. No.: 19/545,247

(22) Filed: Feb. 20, 2026

Related U.S. Application Data
(60) Provisional application No. 63/772,009, filed on Mar. 14, 2025.

(51) Int. Cl. H10B 12/00

(52) U.S. Cl. CPC H10B 12/33; H10B 12/05; H10B 12/482

(57) ABSTRACT

A microelectronic device includes memory cells respectively including a vertical channel access device including a semiconductor pillar including a source region, a drain region, and a channel region vertically extending from and between the source region and the drain region and a gate electrode horizontally neighboring a sidewall of the semiconductor pillar, the gate electrode vertically overlapping the channel region of the semiconductor pillar. The memory cells respectively also including a storage node device vertically below and coupled to the vertical channel access device. The microelectronic device includes digit line structures individually vertically overlying and coupled to the vertical channel access device of a respective one of the memory cells of the memory array structure, each of the digit line structures contacting a top surface and sidewalls of the semiconductor pillar of the vertical channel access device to which the digit line structure is coupled.

### CROSS-REFERENCE TO RELATED APPLICATIONS

This application claims the benefit under 35 U.S.C. § 119(e) of U.S. Provisional Patent Application Ser. No. 63/772,009, filed Mar. 14, 2025, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices from independently formed microelectronic device structures, and to related microelectronic devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

As the density and complexity of memory arrays for volatile memory devices (e.g., DRAM devices) have increased, so has the complexity of the volatile memory devices. In some instances, horizontally oriented access devices (e.g., horizontal channel access devices) for memory cells of a volatile memory device consume more horizontal real estate within the volatile memory device than is desirable, reducing the memory density of the volatile memory device.

### BRIEF DESCRIPTION OF THE DRAWINGS

FIG. 1A through FIG. 14 include simplified, vertical cross-sectional views of a microelectronic device structure at different processing stages of a method of forming a microelectronic device, according to one or more embodiments of the disclosure;

FIG. 15 shows a simplified perspective view of a digit line structure, a second patterned masking line, and a semiconductor projection according to one or more embodiments of the disclosure;

FIG. 16 is a simplified, schematic, top plan view of a second assembly including a memory array structure according to one or more embodiments of the disclosure; and

FIG. 17 is a schematic block diagram of an electronic system, in accordance with an embodiment of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “proximate,” when utilized to describe positions of elements relative to each other, means that the elements are relatively close or near to each other. For example, where a first element is proximate a horizontal boundary of a second element, the first element is closer to that horizontal boundary than other horizontal boundaries of the second element.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

As used herein, the term “sacrificial material” means and includes a material that is formed and/or employed during a fabrication process but which is subsequently removed, in whole or in part, prior to completion of the fabrication process. A “partially-sacrificial” material means and includes a sacrificial material from which only one or more portions is or are removed prior to completion of the fabrication process. A “wholly-sacrificial” material means and includes a sacrificial material that is substantially entirely removed prior to completion of the fabrication process.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including an semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

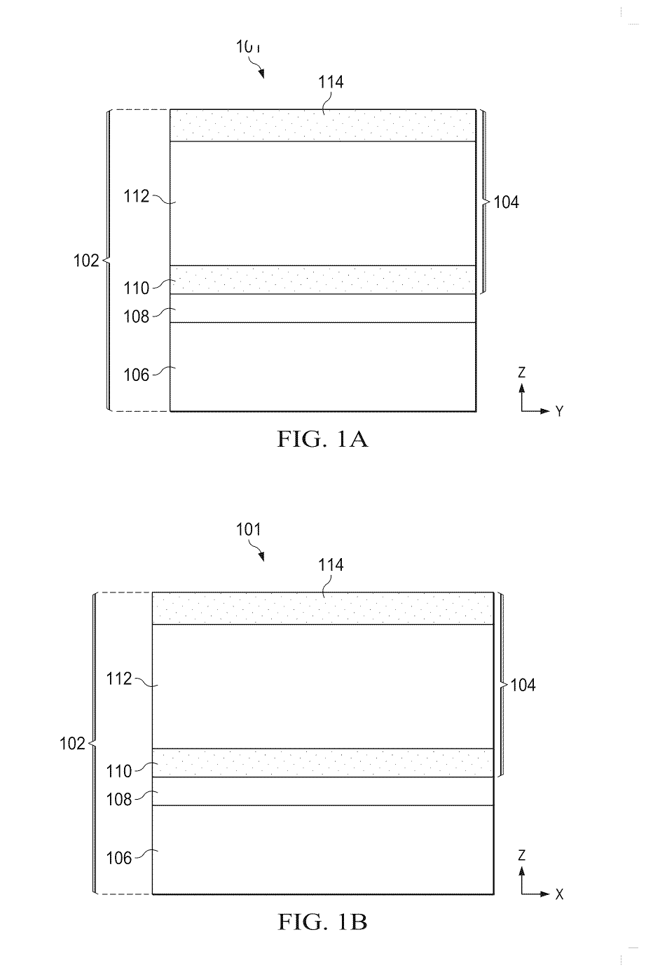

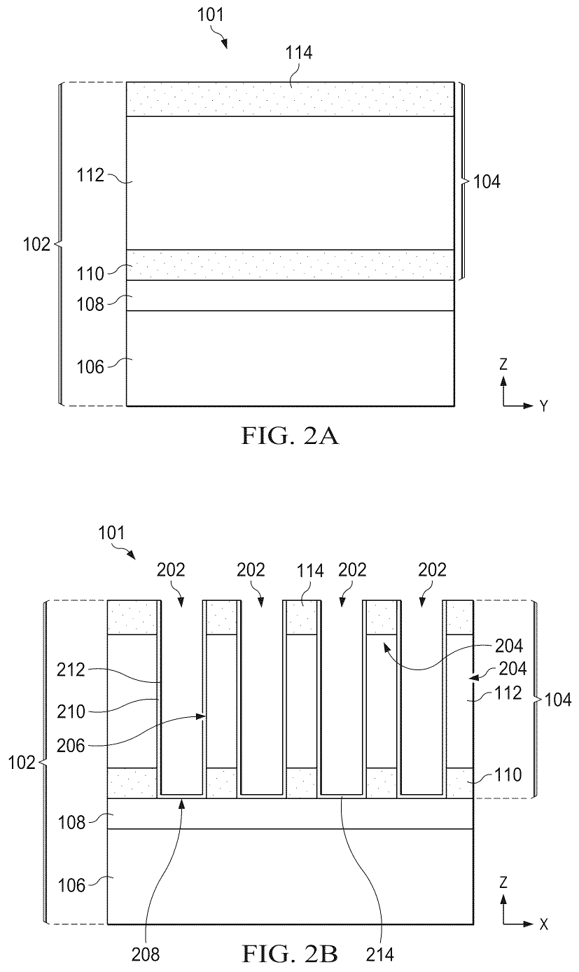

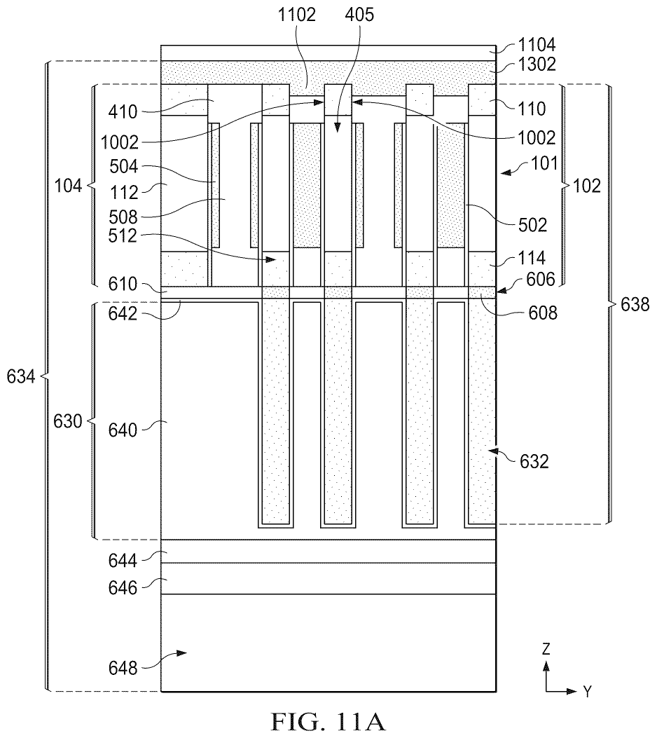

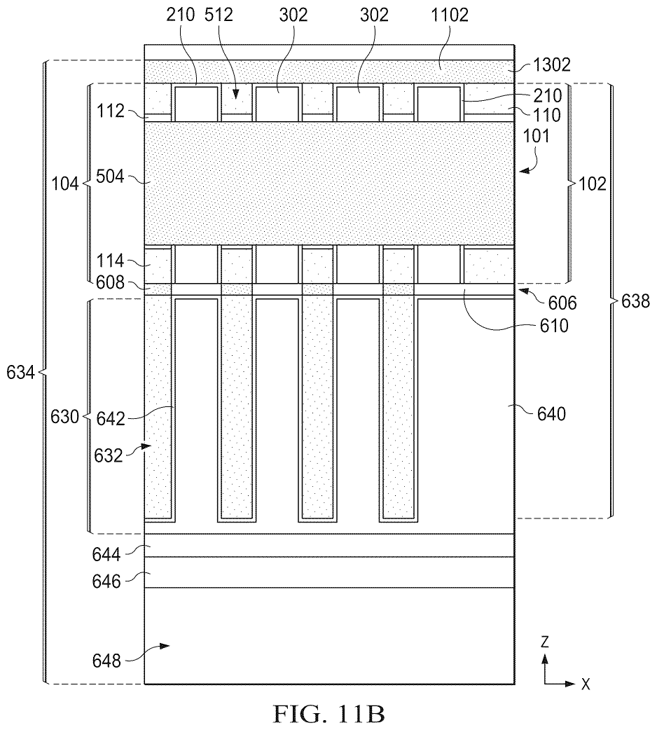

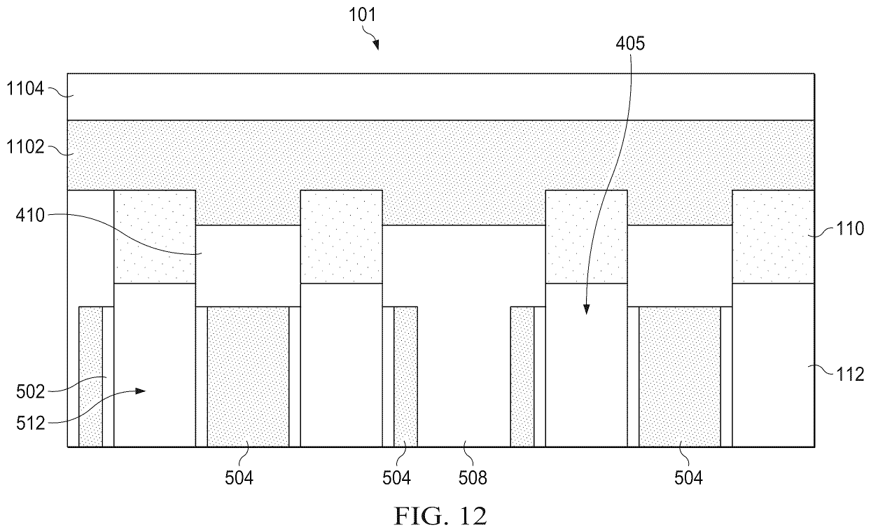

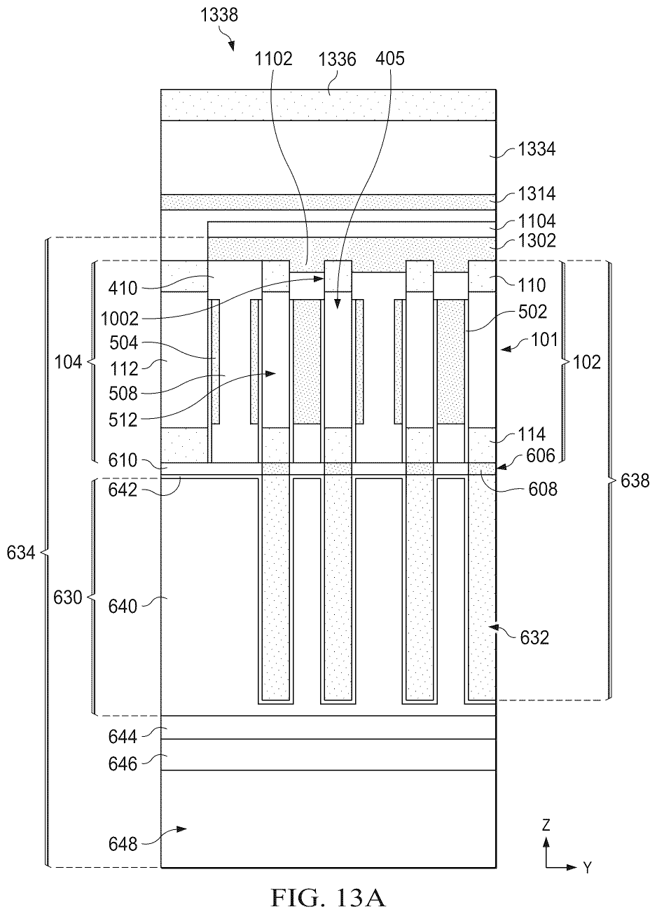

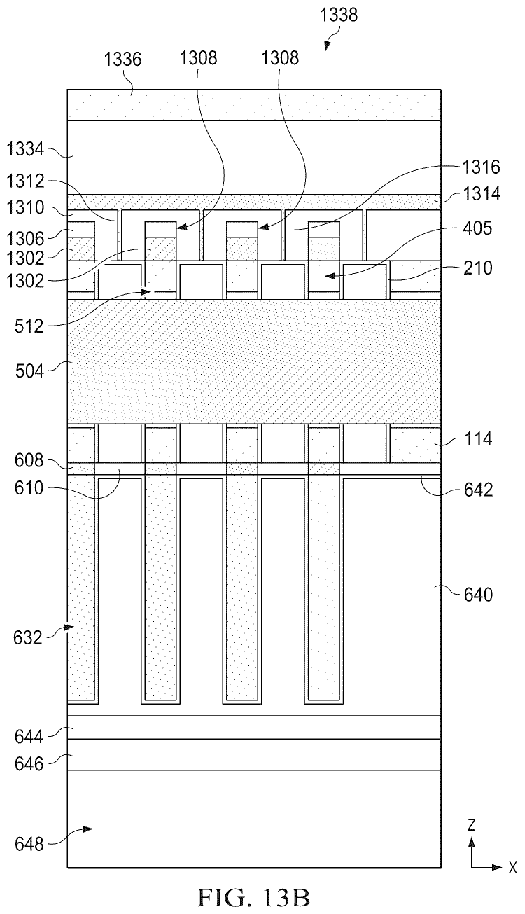

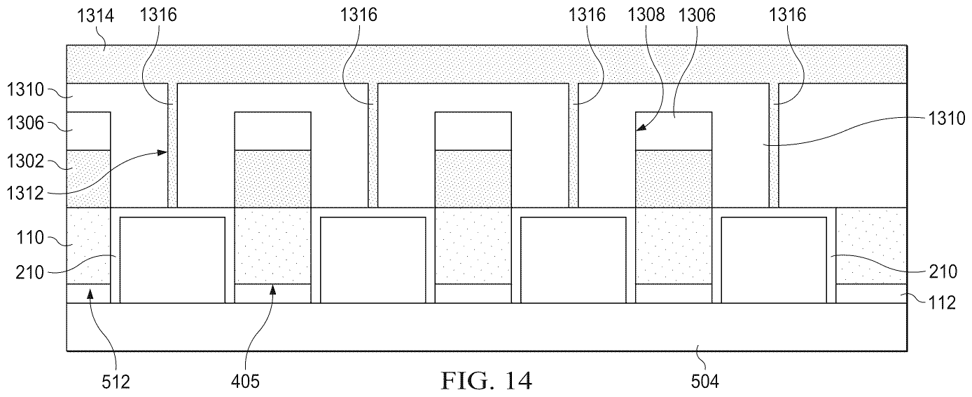

FIG. 1A through FIG. 14 include simplified, vertical cross-sectional views of a microelectronic device structure 101 (e.g., a memory array structure) at different processing stages of a method of forming a microelectronic device (e.g., a memory device, such as a Dynamic Random Access Memory (DRAM) device, a Hierarchical Random Access Memory (HRAM) device, a Ferroelectric Random Access Memory (FeRAM) device, a Synchronous Dynamic Random Access Memory (SDRAM) device, a Magnetoresistive Random Access Memory (MRAM) device), in accordance with embodiments of the disclosure. Specifically, FIGS. 1A, 2A, 3A, 4A, 5A, 6A, 7A, 8A, 9A, 10A, 11A, and 13A include simplified, vertical cross-sectional views of the microelectronic device structure 101 within a ZY plane, and FIGS. 1B, 2B, 3B, 4B, 5B, 6B, 7B, 8B, 9B, 10B, 11B, and 13B include simplified, vertical cross-sectional views of the microelectronic device structure 101 within a ZX plane. FIG. 12 shows an enlarged view of a portion of the vertical cross-sectional view depicted in FIG. 11A. FIG. 14 shows an enlarged view of a portion of the vertical cross-sectional view depicted in FIG. 13B. Furthermore, each respective set of FIGS. (e.g., FIG. 1A and FIG. 1B, FIG. 2A and FIG. 2B, etc.) shows the microelectronic device structure 101 at a same processing stage of a method of forming a microelectronic device but from different vertical cross-sectional views. As a non-limiting example, FIG. 1A and FIG. 1B show the microelectronic device structure 101 at a same processing stage of a method of forming a microelectronic device but from different vertical cross-sectional views. With the description provided below, it will be readily apparent to one of ordinary skill in the art that the methods described herein may be used for forming various devices.

Referring to FIG. 1A and FIG. 1B, forming a microelectronic device structure 101 may include forming a first assembly 102. The first assembly 102 may also be referred to herein as a die or a wafer. The first assembly 102 may at least include a semiconductor material 104 (e.g., a semiconductor wafer), or a base semiconductive material on a support structure or construction upon which additional materials and structures of the microelectronic device structure 101 are formed. In some embodiments, the first assembly 102 includes a first base structure 106 (e.g., a silicon substrate), an etch stop structure 108 (e.g., a semiconductive etch stop structure, such as an SiGe structure; an insulative etch stop structure) formed on or over the first base structure 106, and the semiconductor material 104 formed on or over the etch stop structure 108. In some embodiments, the semiconductor material 104 includes a first semiconductor material (e.g., Si); and the etch stop structure 108 includes a second semiconductor material (e.g., SiGe) having etch selectivity relative to the first semiconductor material. In additional embodiments, the semiconductor material 104 includes a semiconductor material, the etch stop structure 108 includes insulative material, and the semiconductor material 104 and the etch stop structure 108 in combination form a silicon-over-insulator (SOI) substrate.

The semiconductor material 104 may include silicon material, such as epitaxial silicon material (e.g., silicon epitaxially grown on or over the etch stop structure 108). Additionally, the semiconductor material 104 may include a first doped region 110 vertically overlying the etch stop structure 108, an undoped region 112 vertically overlying the first doped region 110, and a second doped region 114 vertically overlying the undoped region 112. In some embodiments, each of the first doped region 110 and the second doped region 114 are n-type doped, such as N-type doped to an N-type dopant concentration within a range of from about 10¹⁵ cm⁻³ to about 10²⁰ cm⁻³. In additional embodiments, one of the first doped region 110 and the second doped region 114 may be N-type doped while the other of the first doped region 110 and the second doped region 114 may be P-type doped, such as P-type doped to a P-type dopant concentration within a range of from about −10¹³ cm⁻³ to about −10¹⁸ cm⁻³. In additional embodiments, one or more of the first doped region 110 is doped (either P-doped or N-doped) to the point of saturation (e.g., greater than or equal to about −10¹⁸ cm⁻³). The doping may be accomplished utilizing any suitable processing, such as by implanting dopant (e.g., at least one N-type dopant or at least one P-type dopant) into the semiconductor material 104. A P-type dopant may include one or more of boron, aluminum, and gallium; and an N-type dopant may include one or more of arsenic, phosphorous, antimony, and bismuth.

In some embodiments, the undoped region 112 does not include any P-type dopants or any N-type dopants. In alternative embodiments, the undoped region 112 is doped with one of the dopants described herein and become another doped region. In such embodiments, a dopant type of the undoped region 112 is different than dopant types of the first doped region 110 and the second doped region 114. For example, if the first doped region 110 and the second doped region 114 respectively include semiconductor material (e.g., epitaxial silicon) doped with at least one N-type dopant, the undoped region 112 may include the semiconductor material (e.g., epitaxial silicon) doped with at least one P-type dopant.

As is discussed in further detail below, in some embodiments, the first doped region 110 forms a drain region of a later-formed vertical channel access device (VCAD) (e.g., vertical channel transistor (VCT)), the undoped region 112 forms a channel region of the later-formed VCAD, and the second doped region 114 forms a source region of the later-formed VCAD.

Referring next to FIG. 2A and FIG. 2B, a first mask material may be formed over the second doped region 114, and the first mask material may be patterned to form first patterned masking lines horizontally extending in parallel with one another in the Y-direction. The first mask material may be patterned into the first patterned masking lines utilizing any suitable methodology. For instance, in some embodiments, a photoresist material is formed on or over the first mask material, is patterned (e.g., photoexposed and developed), and then openings formed in the patterned photoresist material are extended into the first mask material to form the first patterned masking lines. The first patterned masking lines may be removed during subsequent processing stages, or may remain in a final device formed through the methods of the disclosure. The first mask material may be formed of and include a dielectric material, such as a dielectric nitride material (e.g., silicide nitride).

The first patterned masking lines may be employed to form trenches 202 extending vertically into the first assembly 102 and the semiconductor material 104 of the microelectronic device structure 101. The trenches 202 may extend horizontally in parallel in the Y-direction (e.g., a first direction) and may be referred to herein as “y-axis trenches 202.” The y-axis trenches 202 may have any suitable dimensions. In some embodiments, the y-axis trenches 202 have vertical depths (e.g., vertical heights) within a range of from about 100 nm to about 200 nm (e.g., about 150 nm).

The formation of the y-axis trenches 202 effectuates the formation of semiconductor projections 204 (e.g., semiconductor line structures) from the semiconductor material 104. The semiconductor projections 204 have semiconductor side surfaces 206 that are exposed by and partially define boundaries of the y-axis trenches 202. Additionally, upper surfaces 208 of the etch stop structure 108 extending between lower boundaries of the semiconductor side surfaces 206 may also be exposed by and partially define boundaries of the y-axis trenches 202.

In some embodiments, the y-axis trenches 202 are formed using an etching process (e.g., an anisotropic etching process) that selectively removes exposed portions of the semiconductor material 104 (FIG. 1A) relative to the first patterned masking lines without substantially removing portions of the etch stop structure 108. Accordingly, lower boundaries (e.g., bottoms) of the y-axis trenches 202, as defined by upper surfaces 208 of the etch stop structure 108, may be substantially planar.

A first dielectric liner material 210 may be formed in the y-axis trenches 202 and over the semiconductor projections 204 of the microelectronic device structure 101. The first dielectric liner material 210 is formed over and along the semiconductor side surfaces 206 of the semiconductor projections 204 and the upper surfaces of the etch stop structure 108. Within the y-axis trenches 202, the first dielectric liner material 210 may include side portions 212 on the semiconductor side surfaces 206 of the semiconductor projections and bottom portions 214 on or over the upper surfaces 208 of the etch stop structure 108. Within an individual y-axis trench 202, the bottom portion 214 of the first dielectric liner material 210 may be integral and continuous with the side portions 212 of the first dielectric liner material 210. In some embodiments, upper surfaces of the bottom portions 214 of the first dielectric liner material 210 are vertically offset from (e.g., are vertically below) interfaces between the first doped regions 110 and the undoped regions 112 of the individual semiconductor projections 204.

The first dielectric liner material 210 may be formed of and include insulative material. In some embodiments, the first dielectric liner material 210 is formed of and includes silicon dioxide. In some embodiments, the first dielectric liner material 210 is formed (e.g., conformally deposited) inside and outside of the y-axis trenches 202 and portions of the first dielectric liner material 210 outside of the y-axis trenches 202 (e.g., on upper surfaces of the first mask material) remain. In additional embodiments, the first dielectric liner material 210 is formed (e.g., conformally deposited) inside and outside of the y-axis trenches 202 and then portions of the first dielectric liner material 210 are removed (e.g., by way of CMP) while additional portions of the first dielectric liner material 210 within the y-axis trenches 202 are maintained. The side portions 212 and the bottom portions 214 of the first dielectric liner material 210 may have a thickness within a range of from about 3 nm to about 7 nm (e.g., about 5 nm).

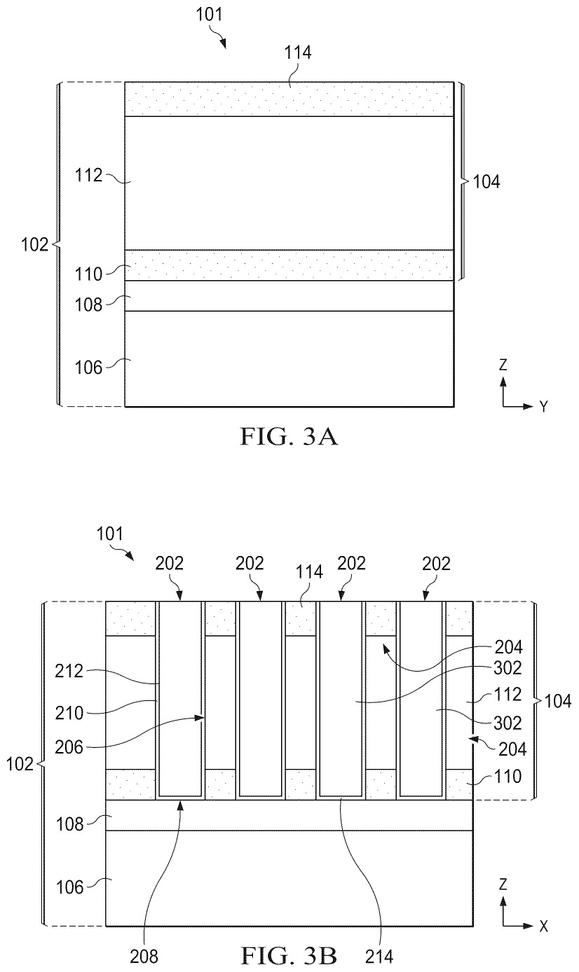

Referring next to FIG. 3A and FIG. 3B, subsequent to forming the first dielectric liner material 210, isolation material 302 may be formed within the y-axis trenches 202. For instance, the y-axis trenches 202 may be at least partially (e.g., substantially) filled with the isolation material 302. In some embodiments, the isolation material 302 is formed of and includes a dielectric oxide material, such as SiOₓ (e.g., SiO₂). The isolation material 302 may be substantially homogeneous, or the isolation material 302 may be heterogeneous. The isolation material 302 may, for example, be formed of and include a stack of at least two different dielectric materials. The isolation material 302 may be formed (e.g., deposited) by way of the manners described herein.

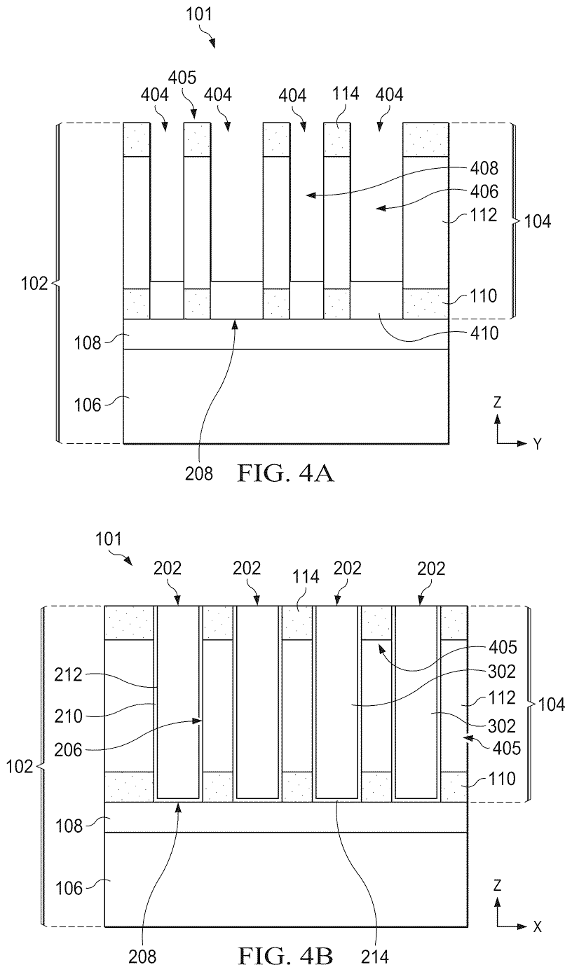

Referring next to FIG. 4A and FIG. 4B, additional trenches 404 may be formed to extend vertically into the first assembly 102 and the semiconductor material 104 of the microelectronic device structure 101. The additional trenches 404 may extend horizontally in parallel in the X-direction (e.g., a second direction) perpendicular to the Y-direction and may be referred to herein as “x-axis trenches 404.”

In some embodiments, the x-axis trenches 404 are formed using an etching process (e.g., an anisotropic etching process) that removes exposed portions of the isolation material 302, the first dielectric liner material 210, the first mask isolation material 302, and the semiconductor projections 204. In some embodiments, the x-axis trenches 404 are formed to terminate (e.g., have lower boundaries) at the upper surface 208 of the etch stop structure 108. Accordingly, lower boundaries (e.g., bottoms) of the x-axis trenches 404 may be defined by upper surfaces 208 of the etch stop structure 108. As a result, semiconductor pillars 405 may be formed from the semiconductor projections 204, and the semiconductor pillars 405 may be distinct and discrete from each other.

In one or more embodiments, some of the x-axis trenches 404 have larger widths, in the Y-direction, than other of the x-axis trenches 404. The x-axis trenches 404 having larger widths may be referred to as “wide x-axis trenches 406” hereinafter, and the x-axis trenches 404 having smaller widths may be referred to as “thin x-axis trenches 408” hereinafter. Furthermore, in some embodiments, each of the wide x-axis trenches 406 are formed in between two thin x-axis trenches 408.

The x-axis trenches 404 may be partially filled within a spacer material 410. In one or more embodiments, the spacer material 410 is deposited within the x-axis trenches 404 through a spin-on coating process. For instance, the spacer material 410 may include a spin-on dielectric. Furthermore, subsequent to the spin-on coating process, the spacer material 410 may be recessed (e.g., removed through an etching process (dry or wet etching process)) to leave only portions of the spacer material 410 at the bottoms of the x-axis trenches 404.

In some embodiments, the spacer material 410 is formed of and includes dielectric oxide material, such as SiOₓ (e.g., SiO₂). In additional embodiments, the spacer material 410 is formed of and includes dielectric nitride material, such as SiN_{y} (e.g., Si₃N₄). The spacer material 410 may be substantially homogeneous, or the spacer material 410 may be heterogeneous. The spacer material 410 may, for example, be formed of and include a stack of at least two different dielectric materials.

The degree to which the spacer material 410 is recessed may serve to position the later-formed gate electrodes (e.g., word line structures) a desired distance from the etch stop structure 108 and a boundary of the first doped region 110 and the undoped region 112 of the semiconductor pillars 405. For instance, the remaining portion of the spacer material 410 may space the later-formed gate electrodes from the etch stop structure 108 and the boundary of the first doped region 110 and the undoped region 112 of the semiconductor pillars 405 by desired distances, and as a result, may space the later-formed gate electrodes from later-formed contacts and/or digit lines (discussed below). For example, the thickness of the spacer material 410 may at least partially determine a distance between the later-formed gate electrodes and a digit line junction. The remaining portion of the spacer material 410 may exhibit a vertical thickness within a range of about 30 nm and about 60 nm. For instance, the spacer material 410 may be etched to have a vertical thickness of about 45 nm.

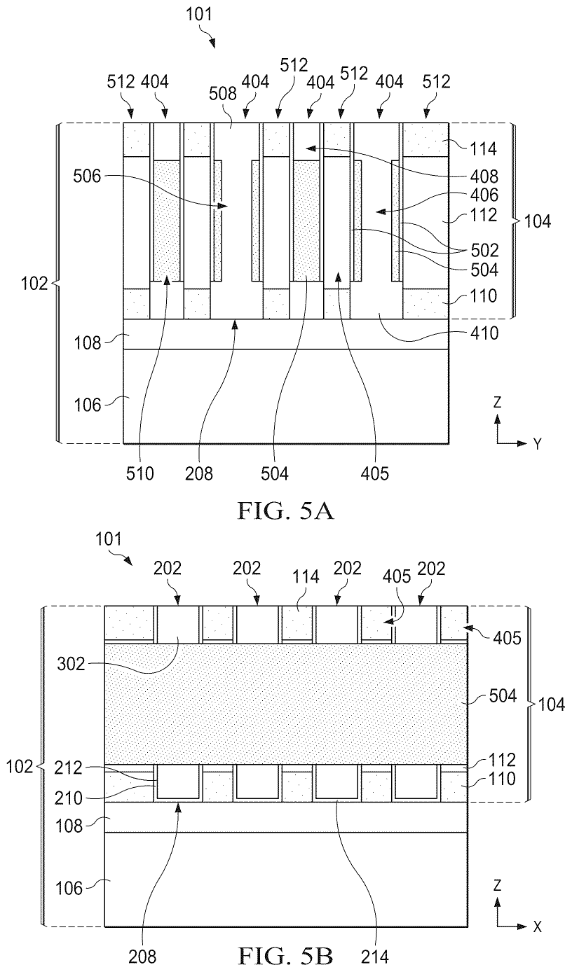

With reference to FIG. 5A and FIG. 5B, a second dielectric liner material 502 (i.e., a gate dielectric material) may be formed in the x-axis trenches 404, over the semiconductor pillars 405, over the isolation material 302, over the first dielectric liner material 210, and over the spacer material 410 of the first assembly 102 of the microelectronic device structure 101. The second dielectric liner material 502 may also be referred to as a gate dielectric material. The second dielectric liner material 502 is formed over and alongside surfaces (e.g., sidewalls) of the semiconductor pillars 405, exposed surfaces of the first dielectric liner material 210, upper surfaces of the spacer material 410, and exposed surfaces of the isolation material 302. In some embodiments, bottom portions of the second dielectric liner material 502 formed over upper surfaces of the spacer material 410 are subsequently removed by way of one or more removal processes.

The second dielectric liner material 502 (e.g., gate dielectric material) may be formed of and include insulative material. In some embodiments, the second dielectric liner material 502 is formed of and includes silicon dioxide. In one or more embodiments, the second dielectric liner material 502 includes a material with a relatively high dielectric constant (k) (e.g., a high-k material) as compared to silicon dioxide, such as a dielectric constant greater than about 3.9 (e.g., greater than or equal to 4, such as greater than or equal to 10, greater than or equal to 20, or greater than or equal to 25). In some embodiments, the second dielectric liner material 502 is formed (e.g., conformally deposited) inside and outside of the x-axis trenches 404. The second dielectric liner material 502 may have a thickness within a range of from about 4 nm to about 6 nm (e.g., about 5 nm).

Word line structures 504 (e.g., access lines, gate electrodes, gate metallization) may be formed on the second dielectric liner material 502 (e.g., on and horizontally neighboring the second dielectric liner material 502) and within the x-axis trenches 404. Additionally, the word line structures 504 may be formed vertically on the spacer material 410. The word line structures 504 may include any of the conductive materials described herein.

In one or more embodiments, the word line structures 504 are formed by at least partially filling the x-axis trenches 404 with a gate electrode material, and subsequently removing one or more portions of the gate electrode material. In some embodiments, the gate electrode material within the wide x-axis trenches 406 are recessed differently than the gate electrode material within the thin x-axis trenches 408.

As non-limiting examples, within the wide x-axis trenches 406, subsequent to depositing the gate electrode material within the x-axis trenches 404, an entirety of the gate electrode material may be recessed down to a desired upper boundary of the word line structures 504, and a center portion of the gate electrode material may be further recessed (e.g., removed) to form first recesses 506 extending vertically through the remaining gate electrode material and to the second dielectric liner material 502 or the spacer material 410. As a result, two word line structures 504 separated by a respective first recess 506 may be formed within each of the wide x-axis trenches 406. Additionally, within the thin x-axis trenches 408, an entirety of the gate electrode material may be recessed down to a desired upper boundary of the word line structures 504, and the remaining gate electrode material forms a given word line structure 504. In view of the foregoing, in some embodiments, the gate electrode material in both the wide x-axis trenches 406 and the thin x-axis trenches 408 are recessed down to a desired upper boundary of the word line structures 504 during a first etching process; and the first recesses 506 are formed within remaining gate electrode material within the wide x-axis trenches 406 in a subsequent, second etching process.

The gate electrode material may be formed (e.g., deposited) through any of the manners described herein. Additionally, recessing the gate electrode material and forming the first recesses 506 in the gate electrode material may be done by conventional techniques, such as by a directional, selective etch process (e.g., an anisotropic etch process, such as an anisotropic dry or wet etch process) that removes the gate electrode material without significantly removing other exposed materials (e.g., the second dielectric liner material 502 or the spacer material 410) of the first assembly 102.

The first recesses 506 may be formed to a desired width (e.g., horizontal dimension) in the Y-direction such that portions of the gate electrode material (e.g., the word line structures 504) remain adjacent to the second dielectric liner material 502 in the Y-direction. In other words, the width of the first recesses 506 may be selected to result in a desired width of the word line structures 504 (e.g., gate electrodes) formed from the gate electrode material in the Y-direction.

The x-axis trenches 404, including the first recesses 506 between the word line structures 504 within the wide x-axis trenches 406, may be filled with a first insulative material 508. The first insulative material 508 may be a spin-on dielectric material, and may be formed by a spin coating process. Moreover, the first insulative material 508 may include any of the dielectric materials described herein. The first insulative material 508 may optionally be subjected to an annealing process.

Additionally, any of the first dielectric liner material 210, the second dielectric liner material 502, and the first insulative material 508 above an upper vertical boundary of the second doped region 114 of the semiconductor pillars 405 may be removed. For example, the first mask spacer material 410 and any of the first dielectric liner material 210, the second dielectric liner material 502, and the first insulative material 508 above an upper vertical boundary of the second doped region 114 of the semiconductor pillars 405 may be removed by way of a CMP process. In some embodiments, some of the second doped regions 114 of the semiconductor pillars 405 are also removed by way of the removal process. As a result, a distance between the word line structures 504 and an upper boundary of the second doped region 114 may be selected. Due to the removal of the first mask spacer material 410 and any of the first dielectric liner material 210, the second dielectric liner material 502, and the first insulative material 508 above an upper vertical boundary (or chosen upper vertical boundary) of the second doped regions 114 of the semiconductor pillars 405, portions of the second doped region 114, the first dielectric liner material 210, the second dielectric liner material 502, and the first insulative material 508 are exposed on a current upper surface of the first assembly 102.

Merged word line structures 504 within the thin x-axis trenches 408 may form a shield gate 510 (also referred to herein as a “back gate structure”) that shields word line structures 504 from cross-interference between word line structures 504. For example, the shield gates 510 may control electrical field interference between vertical channel access devices 512 (e.g., vertical transistors, vertical access devices) that include the semiconductor pillars 405. In some embodiments, the shield gates 510 are formed of and include conductive material, such as one or more of tungsten (W), ruthenium (Ru), molybdenum (Mo), titanium (Ti), alloys thereof, and nitrides thereof. In one or more embodiments, the shield gates 510 are formed of and include semiconductor material (e.g., polysilicon). Furthermore, the shield gates 510 may be operably connected to a respective voltage supply. During use and operation of a microelectronic device of the disclosure (e.g., as described in further detail below with reference to FIG. 13A), the shield gates 510 may be employed to tune electrical properties of the vertical channel access devices 512. For example, the shield gates 510 may be employed to modify threshold voltages of the vertical channel access devices 512 and/or to reduce leakage current (enhancing control over the vertical channels of the vertical channel access devices 512).

An individual vertical channel access device 512 may include a channel region comprising the undoped region 112 of an individual semiconductor pillar 405, a drain region comprising the first doped region 110 of the semiconductor pillar 405, and a source region comprising the second doped region 114 of the semiconductor pillar 405. In addition, the vertical channel access devices 512 may respectively include a gate electrode comprising a portion of one of the word line structures 504, and a gate dielectric material comprising a portion of the second dielectric liner material 502. A given word line structure 504 may be utilized as a gate electrode for multiple vertical channel access devices 512. Furthermore, the back gate structures 510 may respectively be horizontally interposed between neighboring vertical channel access devices 512 in the Y-direction and may extend in parallel in the X-direction.

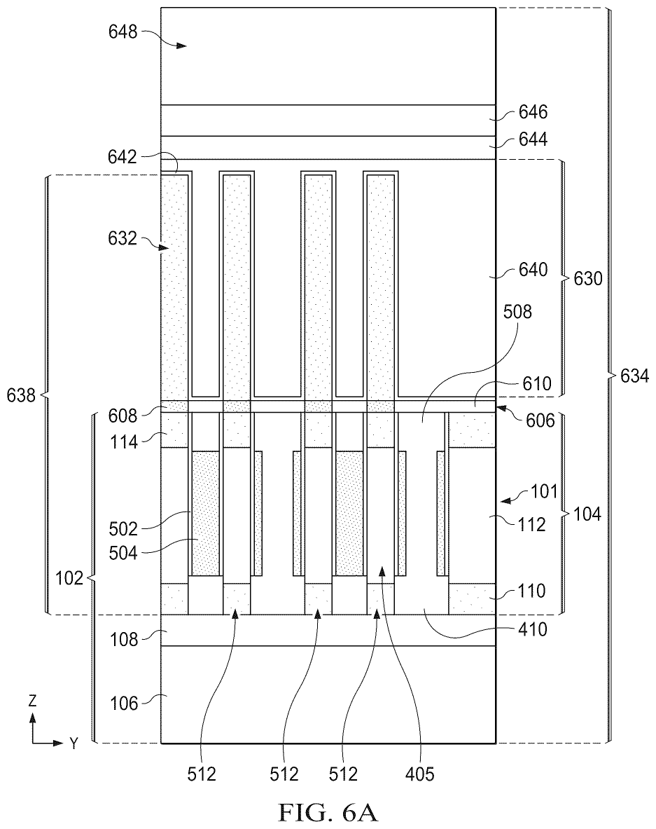

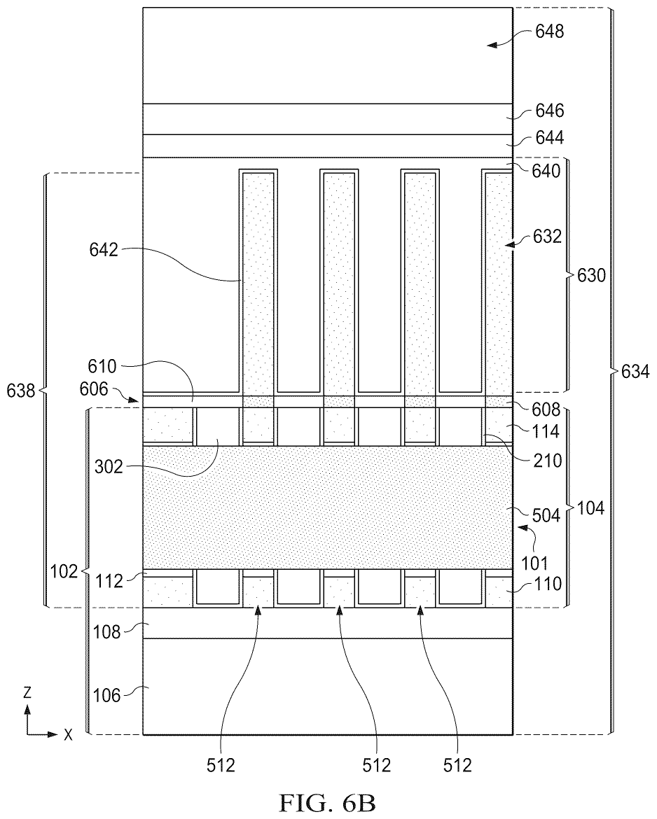

Referring to FIG. 6A and FIG. 6B, a redistribution layer tier 606 (RDL tier 606) including redistribution structures 608 (also referred to herein as “redistribution material (RDM) structures”) and a first dielectric material 610 may be formed over exposed surfaces of second doped regions 114 of the semiconductor pillars 405, the first dielectric liner material 210, the second dielectric liner material 502, the isolation material 302, and the first insulative material 508 of the first assembly 102. The RDM structures 608 may, for example, facilitate a horizontal arrangement (e.g., a hexagonal close packed arrangement) of storage node devices (e.g., capacitors) (described below) that is different than a horizontal arrangement of the semiconductor pillars 405 of the microelectronic device structure 101, while still electrically connecting the semiconductor pillars 405 to the storage node devices. The RDM structures 608 may vertically overlie an array of the vertical channel access devices 512. The RDM structures 608 may be formed of and include one or more of W, Ru, Mo, and TiN_{y}.

A multi-storage node structure 630, including multiple storage node devices 632 (e.g., capacitors), may be formed on or over the RDL tier 606 and the RDM structures 608 to form a second assembly 634, the second assembly 634 including the first assembly 102 and the multi-storage node structure 630. The multi-storage node structure 630 may be formed vertically over the array of the vertical channel access devices 512. The storage node devices 632 may respectively be in electrical contact with one of the RDM structures 608, and one of the vertical channel access devices 512. The storage node devices 632 may be coupled to the vertical channel access devices 512 by way of the RDM structures 608 to form memory cells 638 (e.g., DRAM cells).

Each memory cell 638 may individually include one of the vertical channel access devices 512 (FIG. 5A), one of the storage node devices 632, and one of the RDM structures 608 extending from and between the one of the vertical channel access devices 512 and the one of the storage node devices 632. The storage node devices 632 may individually be formed and configured to store a charge representative of a programmable logic state of the memory cell 638 including the storage node device 632.

In some embodiments, the storage node devices 632 include capacitors. During use and operation, a charged capacitor may represent a first logic state, such as a logic 1; and an uncharged capacitor may represent a second logic state, such as a logic 0. Each of the storage node devices 632 may, for example, be formed to include a first electrode (e.g., a bottom electrode), a second electrode (e.g., a top electrode), and a second dielectric material 642 between the first electrode and the second electrode. For instance, each of the storage node devices 632 may include a metal-insulator-metal (MIM) capacitor. As another example, each of the storage node devices 632 may include a metal-insulator-semiconductor (MIS) capacitor. The collection of memory cells 638 may form a memory array.

The multi-storage node structure 630 may further include a conductive material 640 formed between neighboring storage node devices 632. The conductive material 640 may substantially cover and surround the storage node devices 632. The second electrode of respective ones of the storage node devices 632 may be operatively positioned (e.g., embedded) within the conductive material 640. The conductive material 640 may include any of the conductive materials described herein. For instance, the conductive material 640 may include polysilicon or conductively-doped silicon germanium (SiGe).

A cell plate 644 may be formed on or over the multi-storage node structure 630 of the second assembly 634. For instance, the cell plate 644 may be formed on and over an upper surface of the conductive material 640 of the multi-storage node structure 630. The cell plate 644 may include any of the conductive materials described herein. For instance, the cell plate 644 may include a tungsten (W).

Additionally, a second insulative material 646 may be formed on or over an upper surface of the cell plate 644. In some embodiments, the second insulative material 646 is formed of and includes a dielectric oxide material, such as SiOₓ (e.g., SiO₂). The second insulative material 646 may be substantially homogeneous, or the second insulative material 646 may be heterogeneous. As is discussed in greater detail below, in some embodiments, the second insulative material 646 is utilized to bond the second assembly 634 to another structure (e.g., a carrier structure, a diffusion structure) through dielectric-to-dielectric bonding, such as an oxide-to-oxide bonding.

The cell plate 644 may form an electrode of a common cell multi-capacitor structure (e.g., common structure of metal-insulator-metal (MIM) capacitors, common structure of metal-insulator-semiconductor (MIS) capacitors). In one or more embodiments, the first cell plate 644 and an associated cell capacitor structure are utilized to regulate voltages supplied to one or more of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry. For instance, the cell plate 644 may support and/or form a portion of so called “decoupling capacitors” and/or “pump capacitors.”

Referring still to FIG. 6A and FIG. 6B, a first carrier structure 648 may be attached to the second insulative material 646 of the second assembly 634. The first carrier structure 648 may include a second base structure overlying a third insulative material. In some embodiments, the third insulative material is formed of and includes a dielectric oxide material, such as SiOₓ (e.g., SiO₂). The third insulative material may be substantially homogeneous, or the third insulative material may be heterogeneous.

The second base structure may include a base material or construction upon which additional features (e.g., materials, structures, devices) of the formed. In some embodiments, the second base structure comprises a wafer. The second base structure may be formed of and include one or more of semiconductor material (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride), a base semiconductor material on a supporting structure, glass material (e.g., one or more of BSP, PSG, FSG, BPSG, aluminosilicate glass, an alkaline earth boro-aluminosilicate glass, quartz, titania silicate glass, and soda-lime glass), and ceramic material (e.g., one or more of p-AlN, SOPAN, AlN, aluminum oxide (e.g., sapphire; α-Al₂O₃), and silicon carbide). By way of non-limiting example, the second base structure may comprise a semiconductor wafer (e.g., a silicon wafer), a glass wafer, or a ceramic wafer. The second base structure may include one or more layers, structures, and/or regions formed therein and/or thereon.

To attach the first carrier structure 648 to the second insulative material 646, the third insulative material of the first carrier structure 648 may be provided in physical contact with the second insulative material 646, and the third insulative material and the second insulative material 646 may be exposed to annealing conditions to form bonds (e.g., oxide-to-oxide bonds) between the third insulative material and the second insulative material 646. By way of non-limiting example, the third insulative material and the second insulative material 646 may be exposed to a temperature greater than or equal to about 400° C. (e.g., within a range of from about 300° C. to about 500° C., greater than about 500° C.) to form oxide-to-oxide bonds between the third insulative material and the second insulative material 646. In some embodiments, the third insulative material and the second insulative material 646 are exposed to at least one temperature greater than about 800° C. to form oxide-to-oxide bonds between the third insulative material and the second insulative material 646.

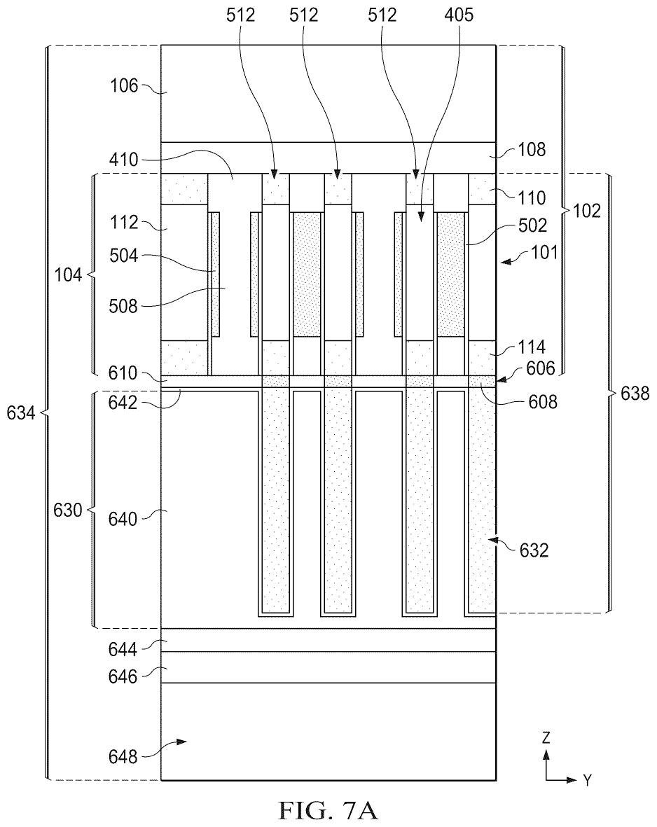

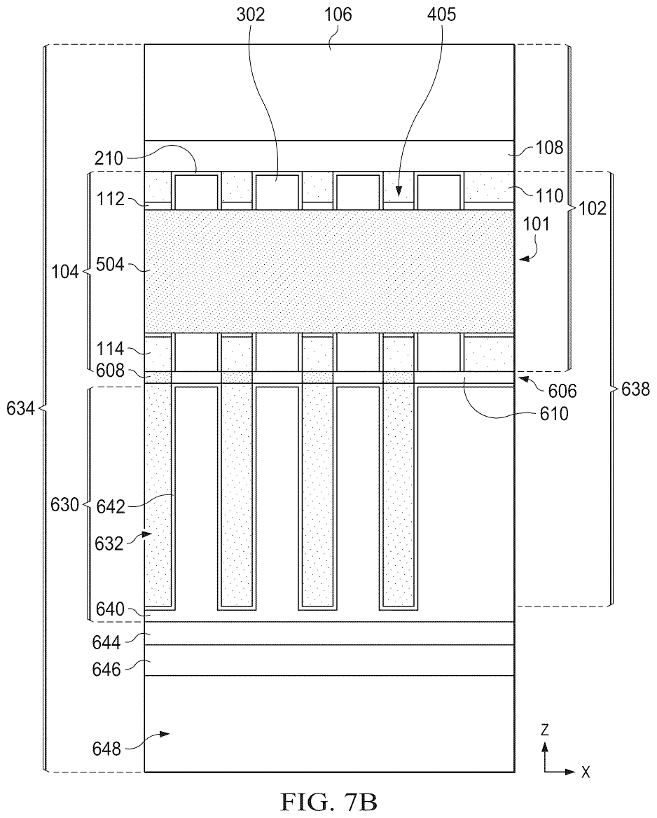

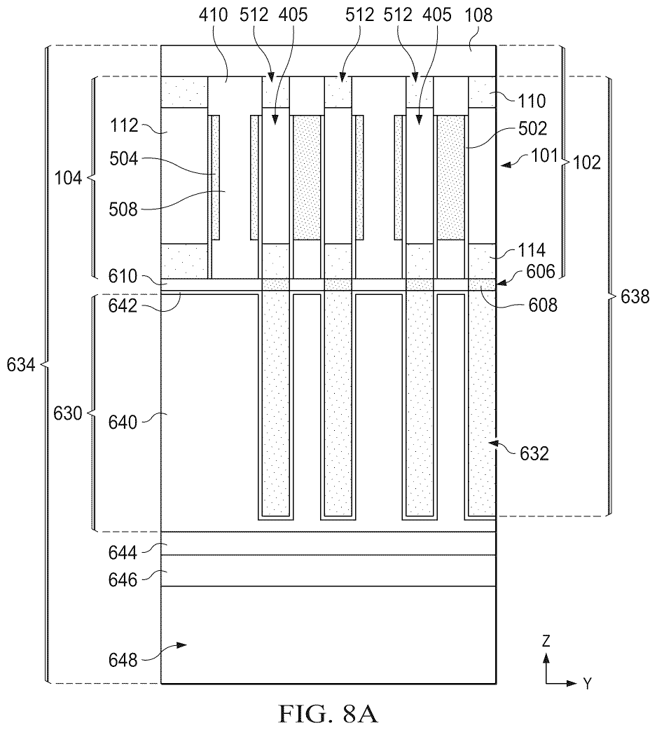

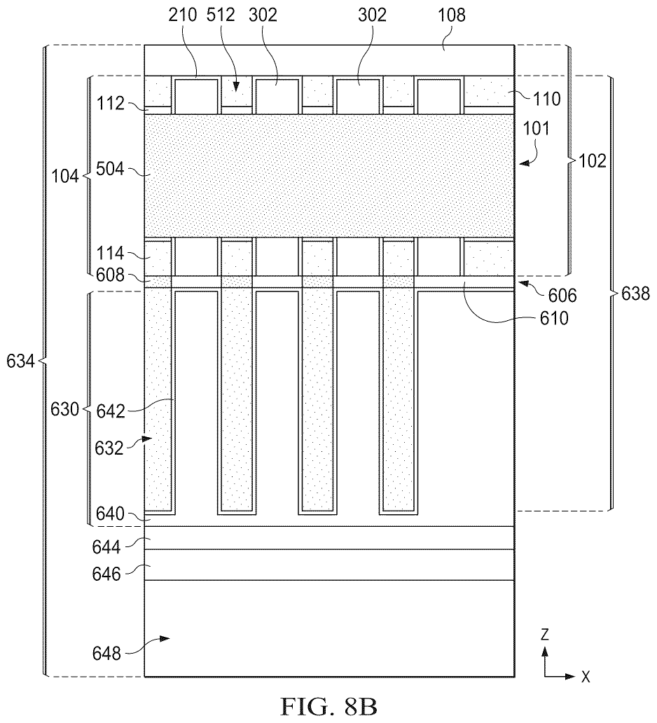

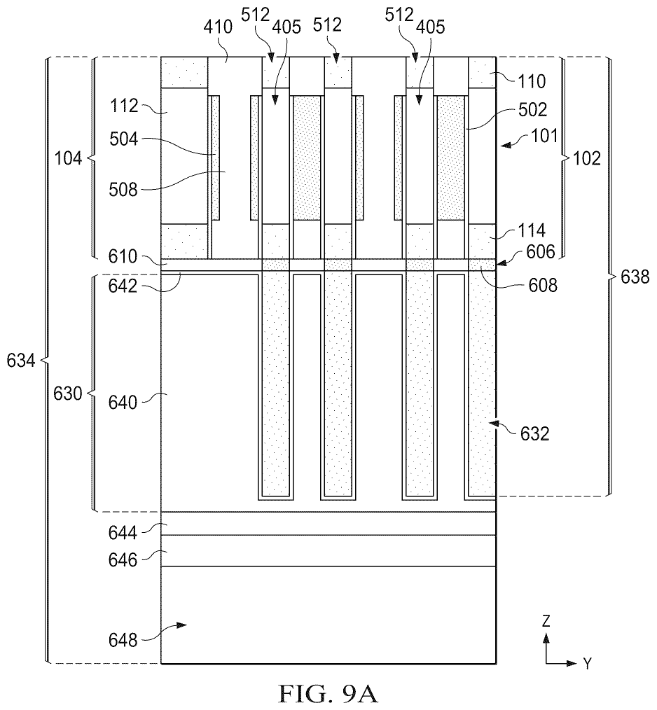

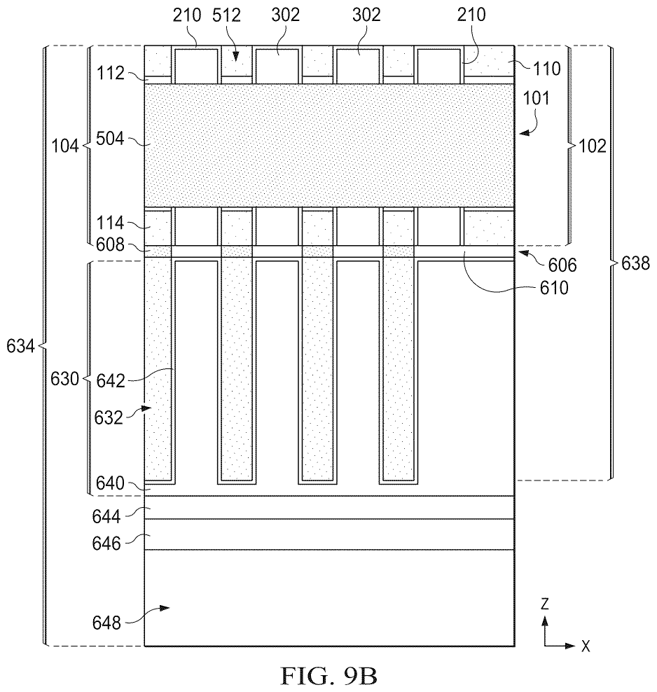

Referring now to FIG. 7A through FIG. 9B, the second assembly 634 may be vertically inverted such that the vertical channel access devices 512 (FIG. 5A) vertically overlie the multi-storage node structure 630 (FIG. 7A and FIG. 7B), and then at least one thinning process (e.g., a CMP process; an etching process, such as a conventional dry etching process or a wet etching process) may be performed on the first base structure 106 and the etch stop structure 108 to remove the first base structure 106 (FIG. 8A and FIG. 8B) and the etch stop structure 108 (FIG. 9A and FIG. 9B). Furthermore, the thinning process may be stopped at upper surfaces (following vertical inversion) of the first dielectric liner material 210, the spacer material 410, and the first doped regions 110 of the semiconductor pillars 405. For instance, the thinning process (e.g., the removal process) may be stopped at part of an intended digit line junction.

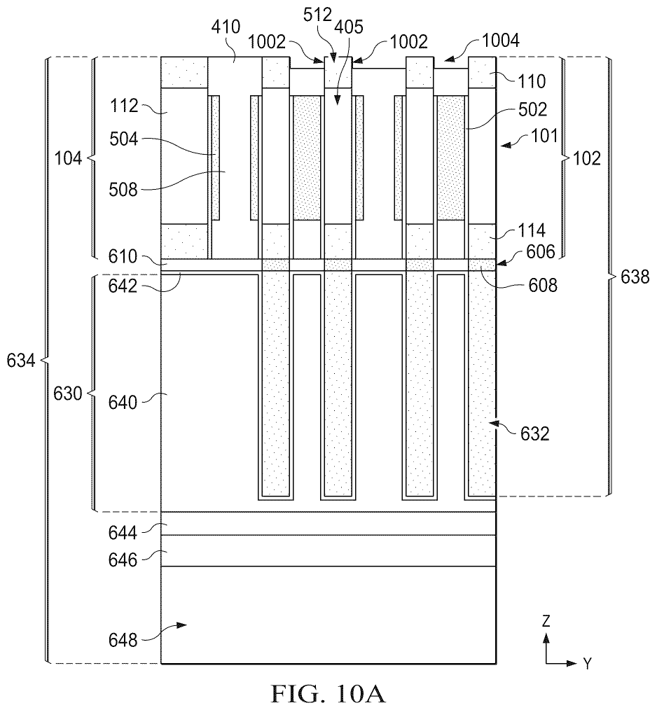

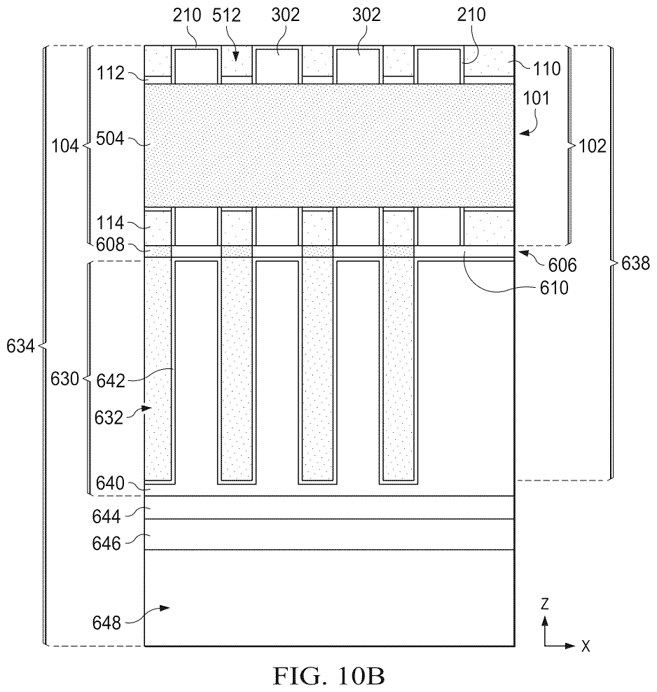

Referring next to FIG. 10A and FIG. 10B, one or more portions of the spacer material 410 not covered by first dielectric liner material 210 (e.g., exposed portions the spacer material 410) may be recessed (e.g., removed through an etching process, such as a dry etching process or a wet etching process). For example, the spacer material 410 within the x-axis trenches 404 (FIG. 4A) may be recessed to expose portions of side surfaces 1002 of the first doped regions 110 of the semiconductor pillars 405. The exposed portions of the side surfaces 1002 of the semiconductor pillars 405 may each lie within an ZX plane.

The spacer material 410 may be recessed by a distance in the Z-direction (e.g., a vertical direction) within a range of about 2 nm to about 6 nm. For example, the spacer material 410 may be recessed by a vertical distance of about 4 nm. Accordingly, the exposed portions of the side surfaces 1002 of the first doped regions 110 of the semiconductor pillars 405 may have vertical heights within a range of about 2 nm to about 6 nm.

Second recesses 1004 formed by recessing the spacer material 410 may terminate (e.g., have lower boundaries) within the spacer material 410. Accordingly, lower boundaries (e.g., bottoms) of the second recesses 1004 may be defined by upper surfaces of the spacer material 410 within the x-axis trenches 404. Furthermore, the lower boundaries (e.g., bottoms) of the second recesses 1004 may vertically overlap with (e.g., be within vertical extents of) the first doped regions 110 of the semiconductor pillars 405.

Recessing the spacer material 410 and forming the second recesses 1004 to expose side surfaces 1002 of the semiconductor pillars 405 may be done by conventional techniques, such as by a directional, selective etch process (e.g., an anisotropic etch process, such as an anisotropic dry or wet etch process) that removes the spacer material 410 without significantly removing other exposed materials (e.g., the first dielectric liner material 210) or the first doped regions 110 of the semiconductor pillars 405 of the first assembly 102. As is discussed in greater detail below, by exposing portions of the side surfaces 1002 of the first doped regions 110 of the semiconductor pillars 405 of the first assembly 102, areas of contacts between later-formed digit line structures and the semiconductor pillars 405 of the first assembly 102 are increased relative to areas of contact provided by only top surfaces of the semiconductor pillars 405 (e.g., top surfaces of the first doped regions 110) alone. Furthermore, as is discussed in greater detail below, the sizes (e.g., areas) of the contacts may be at least partially selected by selecting a depth of the second recesses 1004 (e.g., a distance by which the spacer material 410 is recessed).

Referring collectively to FIG. 11A, FIG. 11B, and FIG. 12, conductive material 1102 may be formed on or over exposed surfaces (e.g., upper surfaces and portions of the side surfaces 1002) of the semiconductor pillars 405 and within the second recesses 1004 of the first assembly 102. In particular, the conductive material 1102 is formed vertically on or over each of the upper surfaces of the semiconductor pillars 405 and horizontally adjacent to (e.g., neighboring) and in contact with the exposed portions of the side surfaces 1002 of the semiconductor pillars 405.

In view of the foregoing, longitudinal ends of the semiconductor pillars 405 (and, hence, the vertical channel access devices 512) may be partially embedded within the conductive material 1102. As used herein, the term “embedded” and derivative terms, when used to refer to a first object being partially embedded within a second object, mean that a portion of at least one major horizontal surface and a portion at least one major vertical surface of the first object are surrounded by (e.g., in physical contact with) the second object. For example, a first object is partially embedded within the second object when at least one major horizontal surface and at least one major vertical surface of the first object are in contact with the second object.

The conductive material 1102 may include one or more of W, Ru, Mo, Ti, alloys thereof, and nitrides thereof. In some embodiments, the conductive material 1102 includes W. The conductive material 1102 may also include one or more conductive barrier materials (e.g., oxidation-resistant materials which protect a bulk metal-containing material thereof from oxidation in embodiments in which the bulk metal-containing material may be exposed to oxygen).

Additionally, a third mask material 1104 may be formed over an upper surface of the conductive material 1102. In some embodiments, the third mask material 1104 is formed of and includes dielectric nitride material (e.g., silicon nitride).

Referring collectively to FIG. 13A, FIG. 13B, and FIG. 14, digit line structures 1302 (e.g., bit line structures, data line structures) may be formed from the conductive material 1102. The digit line structures 1302 may be formed to any suitable dimensions (e.g., width, thickness). By way of example, the digit line structures 1302 may individually be formed to a width, in the X-direction, equal to about the width of an individual semiconductor pillars 405 (e.g., within a range of from about 10 nm to about 30 nm). The digit line structures 1302 may be formed to any suitable pitch. The digit line structures 1302 may be spaced apart from one another by a distance equal to about the distance between the semiconductor pillars 405 horizontally neighboring one another in the X-direction.

The digit line structures 1302 may be formed using any suitable processing. For instance, the third mask material 1104 may be patterned to form second patterned masking lines 1306 horizontally extending in parallel with one another in the Y-direction. The third mask material 1104 may be patterned into the second patterned masking lines 1306 utilizing any suitable methodology. For instance, in some embodiments, a photoresist material is formed on or over the third mask material 1104, is patterned (e.g., photo exposed and developed), and then openings formed in the patterned photoresist material are extended into the third mask material 1104 to form the second patterned masking lines 1306.

The second patterned masking lines 1306 may be employed to form additional y-axis trenches 1308 extending vertically through the conductive material 1102 of the microelectronic device structure 101. The additional y-axis trenches 1308 may extend horizontally in parallel in the Y-direction. The additional y-axis trenches 1308 may have any suitable dimensions. For instance, the additional y-axis trenches 1308 may have a width, in the X-direction, at least substantially equal to about the width of an individual space between neighboring semiconductor pillars 405.

In some embodiments, the additional y-axis trenches 1308 are formed using an etching process (e.g., an anisotropic etching process) that selectively removes exposed portions of the conductive materials 1102 relative to the second patterned masking lines 1306 without removing portions of the first dielectric liner material 210. Accordingly, lower boundaries (e.g., bottoms) of the additional y-axis trenches 1308, as defined by upper surfaces of the first dielectric liner material 210, may be substantially planar.

In view of the foregoing, the digit line structures 1302 vertically overlie and are coupled to the semiconductor pillars 405 of the vertical channel access devices 512 of the memory cells 638. Furthermore, upper longitudinal ends of each of the semiconductor pillars 405 may be partially embedded within a respective digit line structure 1302 of the digit line structures 1302. Moreover, the lowermost surfaces of each digit line structure 1302 may be at a lower elevation than top surfaces of each of the semiconductor pillars 405 of the vertical channel access devices 512 of memory cells 638 to which the digit line structure 1302 is coupled.

A third dielectric liner material 1310 may be formed within the additional y-axis trenches 1308 and over the digit line structures 1302 and the second patterned masking lines 1306 of the microelectronic device structure 101. For instance, the third dielectric liner material 1310 may be formed (e.g., conformally deposited) inside the additional y-axis trenches 1308 and over the digit line structures 1302 and second patterned masking lines 1306. In some embodiments, the third dielectric liner material 1310 does not entirely fill the additional y-axis trenches 1308. For instance, third recesses 1312 may remain between portions the third dielectric liner material 1310 deposited on the sidewalls of the digit line structures 1302 and the second patterned masking lines 1306 of the microelectronic device structure 101.

Within the additional y-axis trenches 1308, the third dielectric liner material 1310 may include side portions on the side surfaces of the digit line structures 1302 and the second patterned masking lines 1306, and, optionally, bottom portions on or over the upper surfaces of the first dielectric liner material 210.

The third dielectric liner material 1310 may be formed of and include insulative material. In some embodiments, the third dielectric liner material 1310 is formed of and includes silicon dioxide. The third dielectric liner material 1310 may have a thickness within a range of from about 3 nm to about 7 nm (e.g., about 5 nm).

A shield structure 1314 (also referred to herein as a “digit line shield structure,” a “upper shielding plate,” or a “top shielding plate”) may be formed over the third dielectric liner material 1310. For instance, material of the shield structure 1314 may be deposited (e.g., conformally deposited) within the third recesses 1312 and over the third dielectric liner material 1310. The shield structure 1314 may at least substantially entirely fill the third recesses 1312 and cover an upper surface of the third dielectric liner material 1310. As a result, in some embodiments, the shield structure 1314 includes projections 1316 extending vertically downward between horizontally neighboring digit line structures 1302. Moreover, because the shield structure 1314 at least substantially entirely fills the second recesses 1004, the shield structure 1314 may extend vertically in-between neighboring digit line structures 1302. Put another way, portions of the shield structure 1314 may be horizontally interposed between neighboring digit line structures 1302 of the microelectronic device structure 101.

The shield structure 1314 may be configured and positioned to shield (e.g., protect) features (e.g., structures, materials, devices, digit lines) within portions of the memory cells 638 (e.g., vertical channel access devices 512 (FIG. 5A)) of the microelectronic device structure 101 from undesirable electrical interference (e.g., electromagnetic interference (EMI)).

In some embodiments, the third dielectric liner material 1310 at least substantially fills the additional y-axis trenches 1308, and the shield structure 1314 is formed over a substantially uniform or continuous upper surface of the third dielectric liner material 1310. As a result, in some embodiments, the shield structure 1314 does not include the projections 1316 extending vertically downward between horizontally neighboring digit line structures 1302 and, rather, includes a generally flat structure.

In view of the foregoing, the shield structure 1314 may vertically overlie the digit line structures 1302, which vertically overlie the vertical channel access devices 512 of the memory cells 638. Accordingly, the vertical channel access devices 512 of the memory cells 638 may be vertically interposed between the digit line structures 1302 and the storage node devices 632 of the memory cells 638.

The shield structure 1314 may be formed of and include conductive material. In some embodiments, the shield structure 1314 is formed of and includes metallic material, such as one or more of at least one metal, at least one alloy, and at least one conductive metal-containing material (e.g., a conductive metal nitride, a conductive metal silicide, a conductive metal carbide, a conductive metal oxide). By way of non-limiting example, the shield structure 1314 may be formed of and include one or more of W, Ru, Mo, Ti, alloys thereof, and nitrides thereof. In some embodiments, the shield structure 1314 is formed of and includes W. The shield structure 1314 may be substantially homogeneous, or the shield structure 1314 may be heterogeneous. If the shield structure 1314 is heterogeneous, amounts of one or more elements included in the shield structure 1314 may vary stepwise (e.g., change abruptly), or may vary continuously (e.g., change progressively, such as linearly, parabolically) throughout different portions of the shield structure 1314. The shield structure 1314 may, for example, be formed of and include a stack of at least two different conductive materials.

Referring to FIG. 13A through FIG. 14 together, a fourth insulative material 1334 may be formed on or over the shield structure 1314. In some embodiments, the fourth insulative material 1334 is formed (e.g., deposited) through any of the manners described herein. Furthermore, the fourth insulative material 1334 may be formed to have an at least substantially planar upper surface. In one or more embodiments, the fourth insulative material 1334 is formed of and includes a dielectric oxide material, such as SiOₓ (e.g., SiO₂). The fourth insulative material 1334 may be substantially homogeneous, or the fourth insulative material 1334 may be heterogeneous. In later processes, one or more interconnect structures and routing tiers may be formed within and vertically overlapping with the fourth insulative material 1334.

A fifth insulative material 1336 may be formed on or over the fourth insulative material 1334 and any formed interconnect structures (e.g., routing structures, contact structures). The fifth insulative material 1336 may be formed (e.g., deposited) through any of the manners described herein. Furthermore, the fifth insulative material 1336 may be formed to have an at least substantially planar upper surface. In one or more embodiments, the fifth insulative material 1336 is formed of and includes dielectric oxide material, such as SiOₓ (e.g., SiO₂). The fifth insulative material 1336 may be substantially homogeneous, or the fifth insulative material 1336 may be heterogeneous. In some embodiments, the fifth insulative material 1336 is utilized to bond the microelectronic device structure 101 to another structure (e.g., a control circuitry structure) through dielectric-to-dielectric bonding, such as an oxide-to-oxide bonding.

The structure depicted in FIG. 13A through FIG. 14 represents an at least partially formed microelectronic device 1338, which may be added thereto, as noted above, by bonding one or more additional structures thereto.

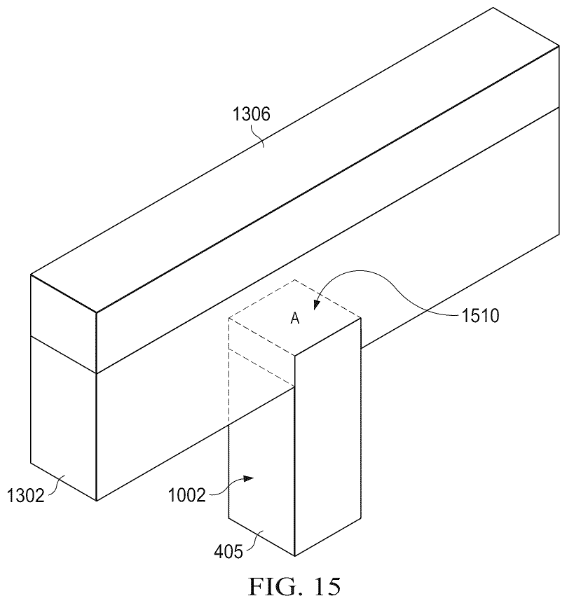

FIG. 15 shows a simplified perspective view of a digit line structure 1302, a second patterned masking line 1306, and a semiconductor pillar 405 according to one or more embodiments of the disclosure. Dotted lines are included to depict structure of the semiconductor pillar 405 obscured by the digit line structure 1302.

As is shown in FIG. 15, because the spacer material 410 (FIG. 4A) is recessed, as discussed above in regard to FIG. 10A, the digit line structure 1302 may contact the semiconductor pillar 405 of an individual vertical channel access device 512 (FIG. 13A and FIG. 13B) on a top surface 1510 of the semiconductor pillar 405 and exposed portions of side surfaces 1002 of the semiconductor pillar 405. Accordingly, a total contact area between the digit line structure 1302 and the semiconductor pillar 405 may be at least substantially equivalent to a sum of an area of the top surface 1510 of the semiconductor pillar 405, an area of an exposed portion of a first side surface 1002 of the semiconductor pillar 405, and an area of an exposed portion of a second, opposite side surface 1002 of the semiconductor pillar 405.

Put another way, a contact area between a given digit line structure 1302 of the digit line structures 1302 and a given semiconductor pillar 405 of an individual vertical channel access device 512 (FIG. 13A and FIG. 13B) of an individual memory cell 638 (FIG. 13A and FIG. 13B) may include a sum of a first area of the top surface 1510 of the semiconductor pillar 405, a second area of a first portion of a first vertical side surface 1002 of the given semiconductor pillar 405 extending vertically downward from a first horizontal boundary of the top surface 1510, and a third area of a second portion of a second vertical side surface 1002 of the given semiconductor pillar 405 extending vertically downward from a second horizontal boundary of the top surface 1510, opposite the first horizontal boundary.

The second area may be at least substantially equal to an elevation difference between the top surface 1510 of the given semiconductor pillar 405 and a lowermost surface of a portion of the given digit line structure 1302 contacting the first vertical side surface of the given semiconductor pillar 405 multiplied by a width of the semiconductor pillar 405. The third area may be at least substantially equal to an elevation difference between the top surface 1510 of the given semiconductor pillar 405 and a lowermost surface of a portion of the given digit line structure 1302 contacting the second vertical side surface of the given semiconductor pillar 405 multiplied by a width of the semiconductor pillar 405.

The areas of the exposed portions of the first and second side surfaces 1002 are partially dependent on the depth of the second recesses 1004 formed to expose portions of the first and second side surfaces 1002. For example, the area of an exposed portion of a given side surface 1002 of a semiconductor pillar 405 is equivalent to a difference in elevations of the top surface 1510 of the semiconductor pillar 405 and a lowermost surface of the conductive material 1102 or digit line structure 1302 contacting the given side surface 1002 multiplied by a width of the semiconductor pillar 405. In view of the foregoing, sizes (e.g., areas) of the contacts between the digit line structures 1302 and the semiconductor pillars 405 may be at least partially selected by selecting a depth of the second recesses 1004 (e.g., a distance by which the spacer material 410 (FIG. 4A) is recessed).

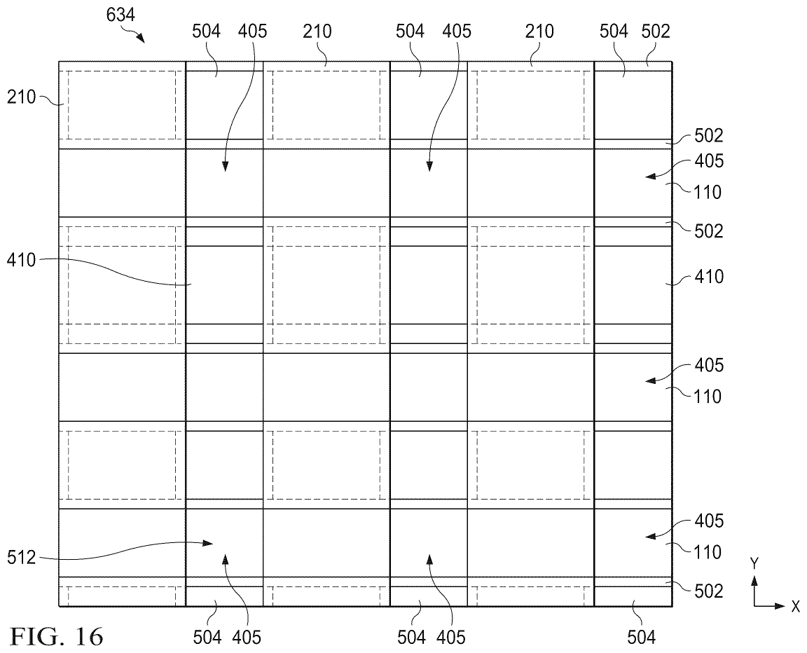

FIG. 16 is a simplified, schematic, top plan view of the second assembly 634 at the stage of processing depicted in FIG. 10A and FIG. 10B. Not every element of the second assembly 634 is depicted within FIG. 16 for clarity and ease of depiction, and one or more elements are depicted at least partially transparent to show elements below the partially transparent elements. The second assembly 634 may include any of the materials, structures, and elements (e.g., dielectric materials, dielectric liner materials, structures, etc.) of the second assembly 634 described above with reference to one or more of FIG. 1A through FIG. 15.

In view of FIG. 1A through FIG. 16, the microelectronic device 1338 of the present disclosure may provide advantages over conventional microelectronic devices. For example, the microelectronic devices 1338 of the present disclosure increase areas of contacts between semiconductor pillars 405 and digit line structures 1302 by exploiting vertical side surfaces 1002 of the semiconductor pillars 405 (e.g., enabling the digit line structures 1302 to at least partially wrap around tops (e.g., top longitudinal ends) of the semiconductor pillars 405). Furthermore, by increasing the areas of contacts between semiconductor pillars 405 and digit line structures 1302 by using the vertical side surfaces 1002 of the semiconductor pillars 405 (e.g., without increasing horizontal widths of the digit line structures 1302), the areas of contacts may be increased without increasing digit line structure 1302-to-digit line structure 1302 capacitance or interference.

Thus, in accordance with some embodiments of the disclosure, a microelectronic device, includes memory cells respectively including: a vertical channel access device comprising: a semiconductor pillar including a source region, a drain region, and a channel region vertically extending from and between the source region and the drain region; and a gate electrode horizontally neighboring a sidewall of the semiconductor pillar, the gate electrode vertically overlapping the channel region of the semiconductor pillar; and a storage node device vertically below and coupled to the vertical channel access device; and digit line structures individually vertically overlying and coupled to the vertical channel access device of a respective one of the memory cells of the memory array structure, each of the digit line structures contacting a top surface and sidewalls of the semiconductor pillar of the vertical channel access device to which the digit line structure is coupled.

In some embodiments, an elevation difference between the top surface of the semiconductor pillar and a lowermost surface of the digit line structure is within a range of about 2 nm and about 6 nm. In some embodiments, the elevation difference between the top surface of semiconductor pillar and the lowermost surface of the digit line structure is about 4 nm.

A contact area between the digit line structure and the semiconductor pillar of the vertical channel access device may include a sum of a first area of the top surface of the semiconductor pillar, a second area of a first portion of a first sidewall extending vertically downward from a first horizontal boundary of the top surface, and a third area of a second portion of a second sidewall extending vertically downward from a second horizontal boundary of the top surface, opposite the first horizontal boundary.

The second area may be at least substantially equal to an elevation difference between the top surface of the semiconductor pillar and a lowermost surface of a portion of the digit line structure contacting the first sidewall of the semiconductor pillar multiplied by a width of the semiconductor pillar. The elevation difference may about 4 nm.

Additionally, in accordance with some embodiments of the disclosure, a method of forming a microelectronic device includes: forming memory cells respectively comprising a vertical channel access device and a storage node device vertically offset from the vertical channel access device; and forming digit line structures respectively vertically offset from and coupled to the vertical channel access device of a respective one of the volatile memory cells, each of the digit line structures contacting a top surface and sidewalls of a semiconductor pillar of the vertical channel access device of the respective one of the memory cells.

Forming the digit line structures may include forming lowermost surfaces of the digit line structures at a lower elevation than an elevation of the top surface of the semiconductor pillar of the vertical channel access device of each of the memory cells.

Forming the digit line structures may include forming the digit line structures such that a contact area between a respective one of the digit line structures and the semiconductor pillar of the vertical channel access device of the respective one of the memory cells includes a sum of a first area of the top surface of the semiconductor pillar, a second area of a first portion of a first sidewall of the semiconductor pillar, extending vertically from a first horizontal boundary of the top surface, and a third area of a second portion of a second sidewall of the semiconductor pillar extending vertically from a second horizontal boundary of the top surface, opposite the first horizontal boundary.

The second area may be at least substantially equal to an elevation difference between the top surface of the semiconductor pillar and a lowermost surface of a portion of the respective one of the digit line structures contacting the first sidewall of the semiconductor pillar multiplied by a horizontal width of the semiconductor pillar.

Furthermore, in accordance with some embodiments of the disclosure, a microelectronic device includes: dynamic random-access memory (DRAM) cells respectively including a vertical channel access device vertically above and coupled to a capacitor; and digit line structures vertically overlying and coupled to the DRAM cells, a lowermost surface of each of the digit line structures at a lower vertical elevation than an uppermost surface of a semiconductor pillar of the vertical channel access device of a respective one of the DRAM cells to which the digit line structure is coupled.

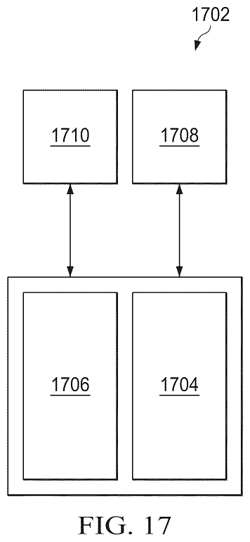

Microelectronic devices (e.g., the microelectronic device 1338 (FIG. 13A and FIG. 13B)) in accordance with embodiments of the disclosure may be used in embodiments of electronic systems of the disclosure. For example, FIG. 17 is a block diagram illustrating an electronic system 1702 according to embodiments of disclosure. The electronic system 1702 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 1702 includes at least one memory device 1704. The memory device 1704 may comprise, for example, a microelectronic device (e.g., the microelectronic device 1338 (FIG. 13A)) previously described herein. The electronic system 1702 may further include at least one electronic signal processor device 1706 (often referred to as a “microprocessor”). The electronic signal processor device 1706 may, optionally, comprise a microelectronic device (e.g., the microelectronic device 1338 (FIG. 13A and FIG. 13B)) previously described herein. While the memory device 1704 and the electronic signal processor device 1706 are depicted as two (2) separate devices in FIG. 17, in additional embodiments, a single (e.g., only one) memory/processor device having the functionalities of the memory device 1704 and the electronic signal processor device 1706 is included in the electronic system 1702. In such embodiments, the memory/processor device may include a microelectronic device (e.g., the microelectronic device 1338 (FIG. 13A and FIG. 13B)) previously described herein. The electronic system 1702 may further include one or more input devices 1708 for inputting information into the electronic system 1702 by a user, such as, for example, a mouse or other pointing device, a keyboard, a touchpad, a button, or a control panel. The electronic system 1702 may further include one or more output devices 1710 for outputting information (e.g., visual or audio output) to a user such as, for example, a monitor, a display, a printer, an audio output jack, a speaker, etc. In some embodiments, the input device 1708 and the output device 1710 comprise a single touchscreen device that can be used both to input information to the electronic system 1702 and to output visual information to a user. The input device 1708 and the output device 1710 may communicate electrically with one or more of the memory device 1704 and the electronic signal processor device 1706.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. Any equivalent embodiments are within the scope of this disclosure. For example, elements and features disclosed in relation to one embodiment may be combined with elements and features disclosed in relation to other embodiments of the disclosure. Various modifications of the disclosure, in addition to those shown and described herein, such as alternate useful combinations of the elements and features described will become apparent to those skilled in the art from the description. Such modifications and embodiments also fall within the scope of the appended claims and equivalents.

What is claimed is:

1. A microelectronic device, comprising:
memory cells respectively comprising:
a vertical channel access device comprising:
a semiconductor pillar comprising a source region, a drain region, and a channel region vertically extending from and between the source region and the drain region; and
a gate electrode horizontally neighboring a sidewall of the semiconductor pillar, the gate electrode vertically overlapping the channel region of the semiconductor pillar; and
a storage node device vertically below and coupled to the vertical channel access device; and
digit line structures individually vertically overlying and coupled to the vertical channel access device of a respective one of the memory cells, each of the digit line structures contacting a top surface and sidewalls of the semiconductor pillar of the vertical channel access device to which the digit line structure is coupled.

2. The microelectronic device of claim 1, wherein an elevation difference between the top surface of the semiconductor pillar and a lowermost surface of the digit line structure is within a range of about 2 nm and about 6 nm.

3. The microelectronic device of claim 2, wherein an elevation difference between the top surface of semiconductor pillar and the lowermost surface of the digit line structure is about 4 nm.

4. The microelectronic device of claim 1, wherein a contact area between the digit line structure and the semiconductor pillar of the vertical channel access device comprises a sum of a first area of the top surface of the semiconductor pillar, a second area of a first portion of a first sidewall extending vertically downward from a first horizontal boundary of the top surface, and a third area of a second portion of a second sidewall extending vertically downward from a second horizontal boundary of the top surface, opposite the first horizontal boundary.

5. The microelectronic device of claim 4, wherein the second area is at least substantially equal to an elevation difference between the top surface of the semiconductor pillar and a lowermost surface of a portion of the digit line structure contacting the first sidewall of the semiconductor pillar multiplied by a width of the semiconductor pillar.

6. The microelectronic device of claim 5, wherein the elevation difference is about 4 nm.

7. The microelectronic device of claim 1, further comprising a shield structure vertically overlying the digit line structures.

8. The microelectronic device of claim 7, wherein the shield structure comprises projections that extend vertically between pairs of the digit line structures horizontally neighboring one another.

9. The microelectronic device of claim 1, wherein the storage node device comprises a capacitor.

10. A method of forming a microelectronic device, comprising:
forming memory cells respectively comprising a vertical channel access device and a storage node device vertically offset from the vertical channel access device; and
forming digit line structures respectively vertically offset from and coupled to the vertical channel access device of a respective one of the volatile memory cells, each of the digit line structures contacting a top surface and sidewalls of a semiconductor pillar of the vertical channel access device of the respective one of the memory cells.

11. The method of claim 10, wherein forming the digit line structures comprises forming lowermost surfaces of the digit line structures at a lower elevation than an elevation of the top surface of the semiconductor pillar of the vertical channel access device of each of the memory cells.

12. The method of claim 11, wherein an elevation difference between the top surface of the semiconductor pillar of the vertical channel access device and the lowermost surfaces of the digit line structures is within a range of from about 2 nm to about 6 nm.

13. The method of claim 10, wherein forming the digit line structures comprises forming the digit line structures such that the semiconductor pillar of the vertical channel access device to a respective one of the digit line structures is coupled to and is partially embedded within the respective one of the digit line structures.

14. The method of claim 10, wherein forming the digit line structures comprises forming each of the digit line structures to directly physically contact each of the top surface and the sidewalls of the semiconductor pillar of the vertical channel access device of the respective one of the memory cells.

15. The method of claim 10, further comprising forming a shield structure vertically offset from the digit line structures, the digit line structures vertically interposed between the shield structure and the memory cells.

16. The method of claim 10, further comprising forming the memory cells to respectively further comprise redistribution material structure vertically interposed between and coupled to the vertical channel access device and the storage node device.

17. The method of claim 10, wherein forming the digit line structures comprises forming the digit line structures such that a contact area between a respective one of the digit line structures and the semiconductor pillar of the vertical channel access device of the respective one of the memory cells comprises a sum of a first area of the top surface of the semiconductor pillar, a second area of a first portion of a first sidewall of the semiconductor pillar, extending vertically from a first horizontal boundary of the top surface, and a third area of a second portion of a second sidewall of the semiconductor pillar extending vertically from a second horizontal boundary of the top surface, opposite the first horizontal boundary.

18. The method of claim 17, wherein the second area is at least substantially equal to an elevation difference between the top surface of the semiconductor pillar and a lowermost surface of a portion of the respective one of the digit line structures contacting the first sidewall of the semiconductor pillar multiplied by a horizontal width of the semiconductor pillar.

19. A microelectronic device, comprising:
dynamic random-access memory (DRAM) cells respectively comprising a vertical channel access device vertically above and coupled to a capacitor; and
digit line structures vertically overlying and coupled to the DRAM cells, a lowermost surface of each of the digit line structures at a lower vertical elevation than an uppermost surface of a semiconductor pillar of the vertical channel access device of a respective one of the DRAM cells to which the digit line structure is coupled.

20. The microelectronic device of claim 19, wherein each of the digit line structures contacts the uppermost surface and vertically extending sidewalls of the semiconductor pillar of the vertical channel access device of the respective one of the DRAM cells to which the digit line structure is coupled.
